(19) United States
(12) Patent Application Publication
(10) Pub. No.: US 2022/0243991 A1
(43) Pub. Date: Aug. 4, 2022

(54) WIND-GUIDING TYPE HEAT DISSIPATION MODULE

(71) Applicant: TAIWAN MICROLOOPS CORP., New Taipei City (TW)

(72) Inventor: Chun-Hung LIN, New Taipei City (TW)

(21) Appl. No.: 17/165,350

(22) Filed: Feb. 2, 2021

(51) Int. Cl. F28D 15/02; F28F 1/32

(52) U.S. Cl. CPC F28D 15/0275; F28F 1/32

(57) ABSTRACT

A wind-guiding type heat dissipation module includes a plurality of first fin members and a plurality of second fin members arranged parallelly and staggeredly. Each first fin member has a first left segment having a first left top edge and a first right segment having a first inclined guiding sheets extending towards a first direction. Each second fin member has a second left segment having a second inclined guiding sheet extending towards a second direction and a second right segment having second right top edge. The first direction and the second direction are opposite direction, a height of each first left top edge is equal to or less than a height of a top end of each second inclined guiding sheet, and a height of each second right top edge is equal to or less than a height of a top end of each first inclined guiding sheet.

### BACKGROUND OF THE INVENTION

### Field of the Invention

This disclosure relates to a heat dissipation structure, especially to an airflow guiding type heat dissipation module.

### Description of Related Art

The calculating speed of an electronic component is constantly increased, thus thermal energy generated by the electronic component is getting higher and higher. For effectively solving the problem of high thermal energy, various type of heat dissipation device is developed in the related art for a purpose of dissipating heat, but there are some problems that need to be improved.

Details are provided as follows. A related heat dissipation device includes heat dissipation fins formed through an aluminum extruding processed or heat dissipation fins formed through a stacking means. A wind guiding structure is more easily to be formed in the stacked heat dissipation fins, thus the heat guiding and dissipating performance of the stacked heat dissipation fins are better than that of the aluminum-extruded heat dissipation fins. However, the structure of the stacked heat dissipation fins is complicated, so that the high production cost is a problem that need to be improved.

Accordingly, the applicant of this disclosure has devoted himself for improving the mentioned disadvantages.

### SUMMARY OF THE INVENTION

This disclosure provides an airflow guiding type heat dissipation module, in which each first left top edge is arranged between two of the second inclined guiding sheets adjacent to each other, and each second right top edge is arranged between two of the first inclined guiding sheets adjacent to each other. As a result, the amount of the first inclined guiding sheets and the second inclined guiding sheets may be reduced, thereby the production cost may be decreased.

According to one embodiment, this disclosure provides an airflow guiding type heat dissipation module including: a plurality of first fin members, each having a first left segment and a first right segment, wherein each of the first left segments has a first left top edge, each of the first right segments has a first inclined guiding sheet extending towards a first direction; and a plurality of second fin members, arranged parallelly and staggeredly with the plurality of first fin members, wherein each of the second fin members has a second left segment and a second right segment, each of the second left segments has a second inclined guiding sheet extending towards a second direction, and each of the second right segments has a second right top edge; wherein, the first direction and the second direction are opposite direction, each of the first left top edges is arranged between two of the second inclined guiding sheets adjacent to each other, and a height of each of the first left top edges is equal to or less than a height of a top end of each of the second inclined guiding sheets, each of the second right top edges is arranged between two of the first inclined guiding sheets adjacent to each other, and a height of each of the second right top edges is equal to or less than a height of a top end of each of the first inclined guiding sheets.

Based on what has been disclosed above, each of the fin members having one side formed with the top edge and another side extended with the inclined guiding sheet are firstly manufactured, then the plurality of fin members are forwardly and backwardly arranged with each other in a staggered manner, so that a structure of the plurality of first fin members and the plurality of second fin members arranged staggeredly may be formed, thereby a cost-saving advantage of the airflow guiding type heat dissipation module may be achieved.

### BRIEF DESCRIPTION OF DRAWINGS

FIG. 1 is a perspective exploded view showing the first fin member and the second fin member according to this disclosure;

FIG. 2 is a perspective view showing the assembly of the airflow guiding type heat dissipation module according to this disclosure;

FIG. 3 is a partially enlarged view showing the airflow guiding type heat dissipation module according to this disclosure;

FIG. 4 is a cross sectional view showing the airflow guiding type heat dissipation module according to this disclosure;

FIG. 5 is a perspective exploded view showing the airflow guiding type heat dissipation module according to this disclosure; and

FIG. 6 is another perspective view showing the assembly of the airflow guiding type heat dissipation module according to this disclosure.

### DETAILED DESCRIPTION OF THE INVENTION

An embodiment of this disclosure is described with reference to the drawings.

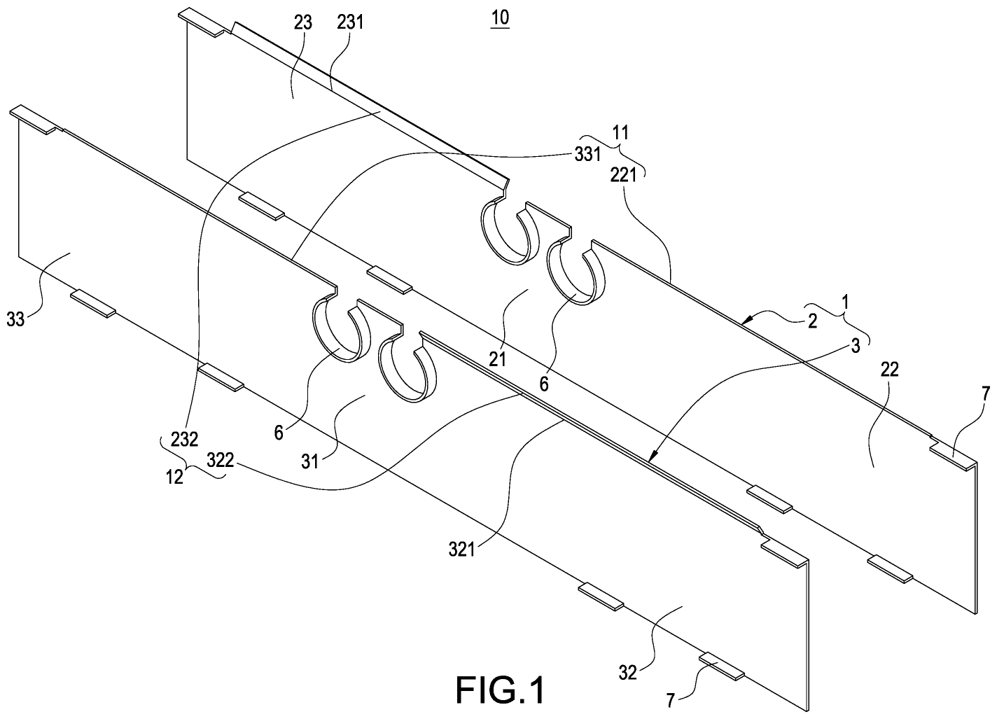

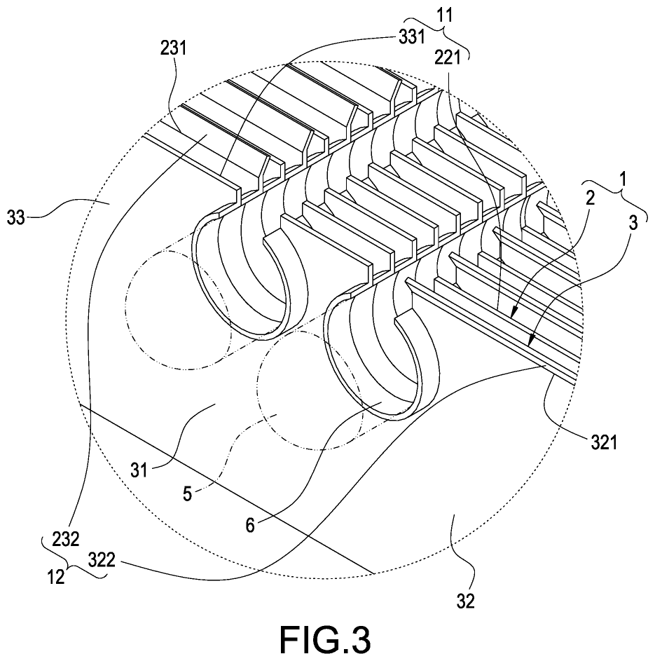

Please refer from FIG. 1 to FIG. 6, this disclosure provides a wind guiding an airflow guiding type heat dissipation module. The airflow guiding type heat dissipation module 10 includes a plurality of fin members 1, and the plurality of fin members 1 are divided into a plurality of first fin members 2 and a plurality of second fin members 3.

As shown from FIG. 1 to FIG. 6, the plurality of fin members 1 are arranged in parallel with each other, a part of the plurality of fin members 1 have a plurality of top edges 11, and a plurality of inclined guiding sheets 12 are extended in the same direction from the top ends of the other part of the plurality of fin members 1. Each of the top edges 11 is arranged between two of the inclined guiding sheets 12 adjacent to each other, and a height of each of the top edges 11 is equal to or less than a height of a top end of each of the included guiding sheets 12.

Details are provided as below. The plurality of first fin members 2 and the plurality of second fin members 3 are arranged parallelly and staggeredly with each other, and an axial center line L is defined by the plurality of first fin members 2 and the plurality of second fin members 3 collectively.

Each of the first fin members 2 has a first middle segment 21, and a first left segment 22 and a first right segment 23 disposed on a left side and a right side of the first middle segment 21 respectively. Each of the second fin members 3 has a second middle segment 31, and a second left segment 32 and a second right segment 33 disposed on a left side and a right side of the second middle segment 31 respectively.

In addition, the plurality of top edges 11 have a plurality of first left top edges 221 formed on each of the first left segments 22 and a plurality of second right top edges 331 formed on each of the second right segments 33.

Moreover, each of the first right segments 23 has a first right top edge 231, each of the second left segments 32 has a second left top edge 321, the plurality of inclined guiding sheets 12 have a plurality of first inclined guiding sheets 232 extended from each of the first right top edges 231 towards a first direction d1 and a plurality of second inclined guiding sheets 322 extended from each of the second left top edges 321 towards a second direction d2.

Moreover, each of the first left top edges 221 is arranged between two of the second inclined guiding sheets 322 adjacent to each other, and a height of each of the first left top edges 221 is not higher than a height of a top end of each of the second inclined guiding sheets 322. In some embodiments, the height of each of the first left top edges 221 is not higher than a height of each of the second left top edges 321. In other words, the height of each of the first left top edges 221 is less than or equal to the height of each of the second left top edges 321, here is not intended to be limiting.

Moreover, each of the second right top edges 331 is arranged between two of the first inclined guiding sheets 232 adjacent to each other, and a height of each of the second right top edges 331 is not higher than a height of a top end of each of the first inclined guiding sheets 232. In some embodiments, the height of each of the second right top edges 331 is not higher than a height of each of the first right top edges 231. In other words, the height of each of the second right top edges 331 is less than or equal to the height of each of the first right top edges 231, here is not intended to be limiting.

The first direction d1 is opposite to the second direction d2, so that an extending direction of each of the first inclined guiding sheets 232 and an extending direction of each of the second inclined guiding sheets 322 are opposite to each other. Each of the first left top edges 221 and each of the second right top edges 331 are arranged on the same level. Aa shape of each of the first inclined guiding sheets 232 and a shape of each of the second inclined guiding sheets 322 are symmetrical to each other The axial center line L, the first direction d1 and the second direction d2 are arranged in parallel with each other.

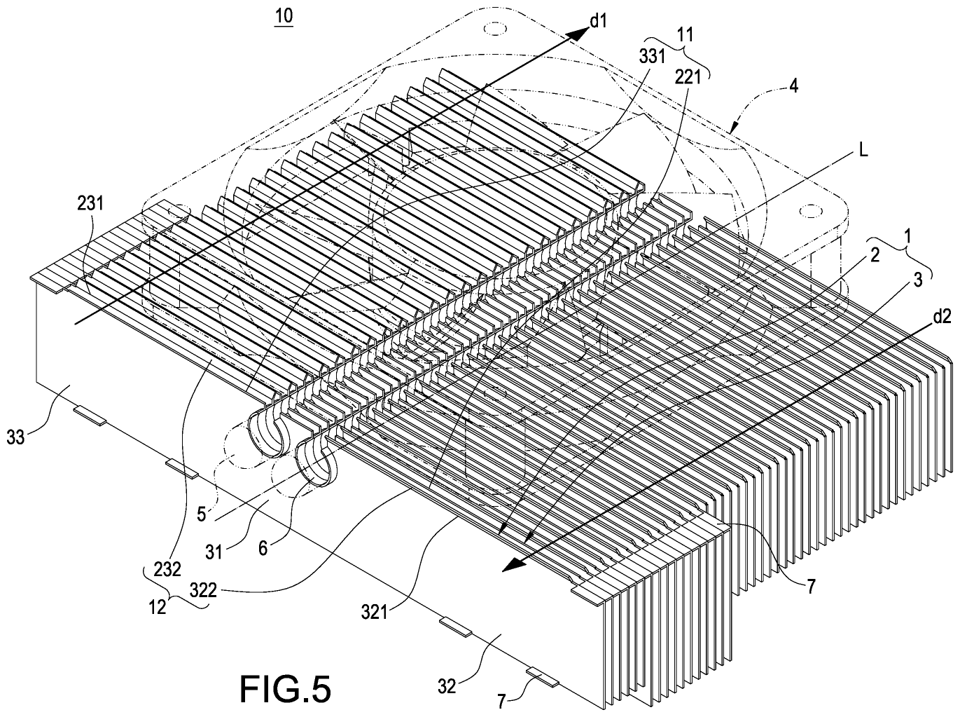

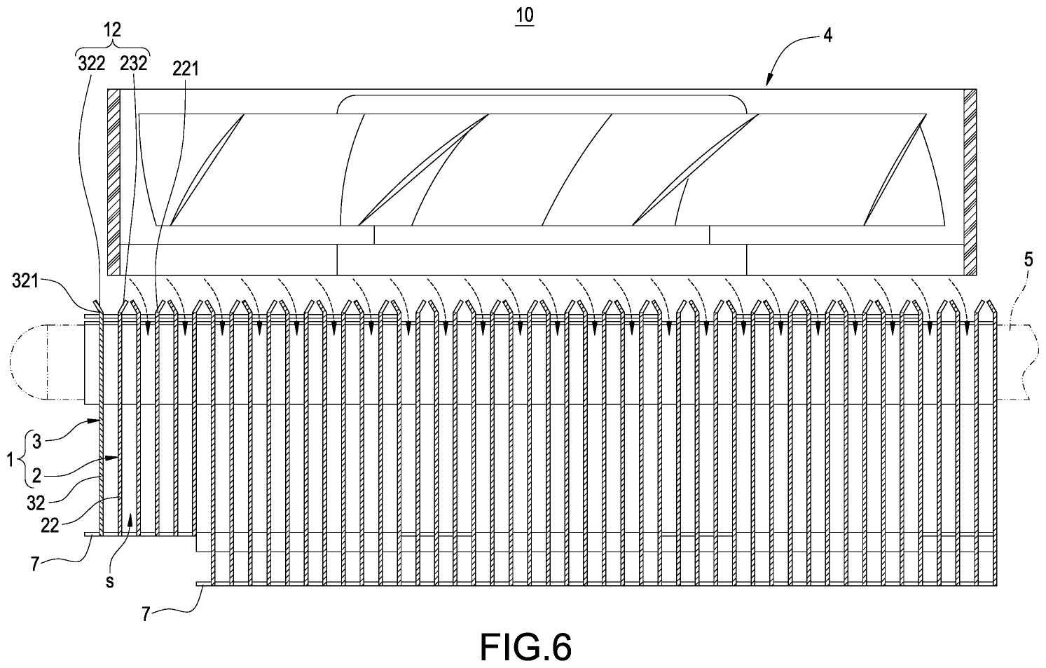

As shown in FIG. 5 and FIG. 6, the airflow guiding type heat dissipation module 10 further includes a fan 4. The fan 4 is disposed on the top ends of the plurality of first fin members 2 and the top ends of the plurality of second fin members 3. A right half side of the fan 4 is arranged corresponding to the plurality of first inclined guiding sheets 232, and a left half side of the fan 4 is arranged corresponding to the plurality of second inclined guiding sheets 322. According to this embodiment, the fan 4 is an axial fan.

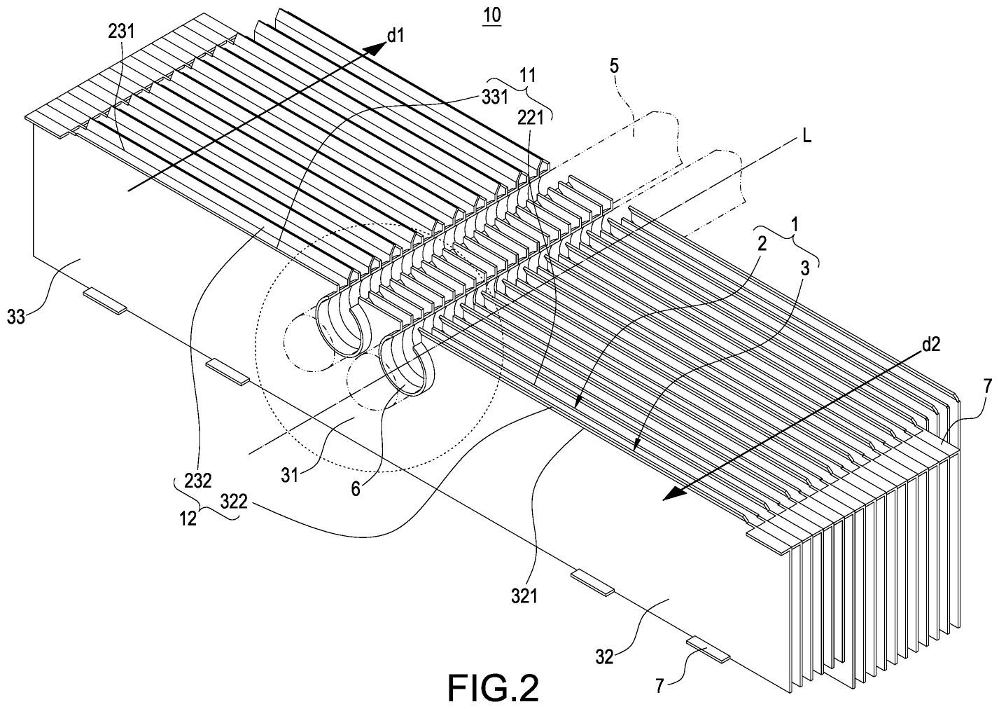

As shown from FIG. 2 to FIG. 6, the airflow guiding type heat dissipation module 10 further includes a plurality of heat pipes 5. A plurality of penetrated holes 6 are formed collectively on the plurality of first middle segments 21 and the plurality of second middle segments 31. Each of the heat pipes 5 passes through each of the penetrated holes 6 and thermally in contact with an inner wall of each of the penetrated holes 6. According to this embodiment, the plurality of heat pipes 5 are disposed corresponding to a central portion of the fan 4, here is not intended to be limiting.

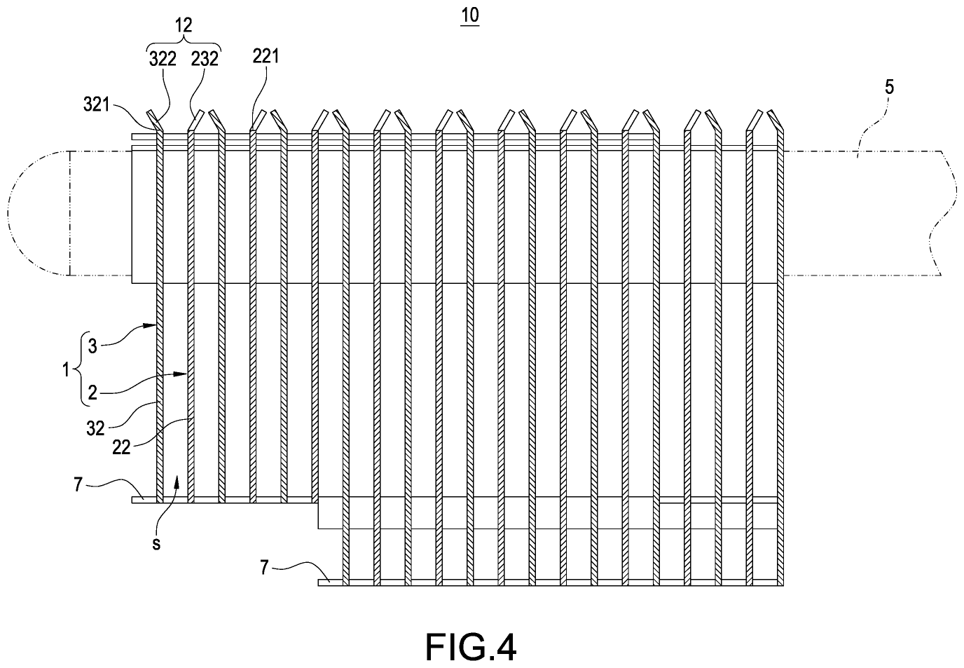

As shown in FIG. 1, FIG. 2, and FIG. 4 to FIG. 6, each of the first fin members 2 and each of the second fin members 3 are extended with a plurality of fixed convex sheets 7. The fixed convex sheets 7 are mutually connected. Each of the fixed convex sheets 7 is arranged between each of the first fin members 2 and each of the second fin members 3, so that a gap is formed between the first fin member 2 and the adjacent second fin member 3 to form an airflow channel s.

As shown from FIG. 2 to FIG. 6, which disclose an operating status of the airflow guiding type heat dissipation module 10 according to this disclosure. Each of the left top edges 221 is arranged between two of the second inclined guiding sheets 322 adjacent to each other, each of the second right top edges 331 is arranged between two of the first inclined guiding sheets 232 adjacent to each other, thus the amount of the first inclined guiding sheets 232 and the second inclined guiding sheets 322 may be reduced and the production cost may be decreased.

In some embodiments, the height of each of the first left top edges 221 is not higher than (namely, is equal to or less than) the height of each of the second left top edges 321, the height of each of the second right top edges 331 is not higher than (namely, is equal to or less than) the height of each of the first right top edges 231, so that the first left top edge 221 may be prevented from blocking one side of the second inclined guiding sheet 322 and affecting a wind guiding effect of the second inclined guiding sheet 322, and the second right top edge 331 may be prevented from blocking one side of the first inclined guiding sheet 232 and affecting a wind guiding effect of the first inclined guiding sheet 232. An airflow generated by the fan 4 may be substantially guided by the first inclined guiding sheets 232 and the second inclined guiding sheets 322 to enter the airflow channel s. Therefore, the heat of the fin members 1 may be dissipated to an external environment via the airflow.

In addition, the fan 4 may be the axial fan, so that the airflows generated from the left half side and the right half side of the fan 4 are in opposite directions. The right half side of the fan 4 is arranged corresponding to the plurality of first inclined guiding sheets 232, the left half side of the fan 4 is arranged corresponding to the plurality of second inclined guiding sheets 322. The extending direction of each of the first inclined guiding sheets 232 and the extending direction of each of the second inclined guiding sheets 322 are opposite, so that the airflows generated from both of the left half side and the right half side of the fan 4 may be guided by each of the first inclined guiding sheets 232 and each of the second inclined guiding sheets 322 to enter the airflow channel s, thereby a heat dissipating efficiency of the airflow guiding type heat dissipation module 10 may be increased.

Moreover, each of the fin members 1 having one side formed with the top edge 11 and another side extended with the inclined guiding sheet 12 is firstly manufactured, then the plurality of fin members 1 are forwardly and backwardly arranged with each other in a staggered manner, so that the plurality of first fin members 2 and the plurality of second fin members 3 arranged staggeredly may be formed. Each of the first left top edges 221 is arranged between two of the second inclined guiding sheets 322 adjacent to each other, and the height of each of the first left top edges 221 is not higher than (namely, is equal to or less than) the height of the top end of each of the second inclined guiding sheets 322, each of the second right top edges 331 is arranged between two of the adjacent first inclined guiding sheets 232 adjacent to each other, and the height of each of the second right top edges 331 is not higher than (namely, is equal to or less than) the height of the top end of each of the first inclined guiding sheets 232. The extending direction of each of the first inclined guiding sheets 232 and the extending direction of each of the second inclined guiding sheets 322 are opposite and the shape of each of the first inclined guiding sheets 232 and the shape of each of the second inclined guiding sheets 322 are symmetrical to each other, so that a cost-saving advantage of the airflow guiding type heat dissipation module 10 may be achieved.

Moreover, according to this embodiment, a manufacturing method of the plurality of penetrated holes 6 and the plurality of fixed convex sheets 7 are as below. The plurality of fin members 1 are divided into the plurality of first fin members 2 and the plurality of second fin members 3 according to forward arrangement or backward arrangement, then the plurality of first fin members 2 and the plurality of second fin members 3 are processed to form the plurality of penetrated holes 6 and the plurality of fixed convex sheets 7 oriented toward the same direction. The manufacturing method of the plurality of penetrated holes 6 and the plurality of fixed convex sheets 7 can be adjusted according the needs, here is not intended to be limiting.

Although this disclosure has been described with reference to the foregoing embodiment, it will be understood that the invention is not limited to the details thereof. Various equivalent variations and modifications can still occur to those skilled in this art in view of the teachings of this disclosure. Thus, all such variations and equivalent modifications are also embraced within the scope of the invention as defined in the appended claims.

1. An airflow guiding type heat dissipation module, comprising:
a plurality of first fin members, each comprising a first middle segment, a first left segment and a first right segment, each of the first left segments comprising a first left top edge, and each of the first right segments comprising a first inclined guiding sheet extending towards a first direction; and
a plurality of second fin members, arranged parallelly and staggeredly with the plurality of first fin members, and each comprising a second middle segment, a second left segment and a second right segment, each of the second left segments comprising a second inclined guiding sheet extending toward a second direction, and each of the second right segments comprising a second right top edge;
wherein, the first direction and the second direction are opposite directions, each of the first left top edges is arranged between two of the second inclined guiding sheets adjacent to each other, and a height of each of the first left top edges is less than a height of a top end of each of the second inclined guiding sheets, each of the second right top edges is arranged between two of the first inclined guiding sheets adjacent to each other, and a height of each of the second right top edges is less than a height of a top end of each of the first inclined guiding sheets.

2. The airflow guiding type heat dissipation module according to claim 1, wherein each of the first left top edges and each of the second right top edges are arranged on a same level, and a shape of each of the first inclined guiding sheets and a shape of each of the second inclined guiding sheets are symmetrical to each other.

3. The airflow guiding type heat dissipation module according to claim 1, wherein each of the first right segments comprises a first right top edge, each of the second left segments comprises a second left top edge, each of the first inclined guiding sheets is extended from a corresponding one of the first right top edges, and each of the second inclined guiding sheets is extended from a corresponding one of the second left top edges.

4. The airflow guiding type heat dissipation module according to claim 3, wherein the height of each of the first left top edges is equal to or less than a height of each of the second left top edges.

5. The airflow guiding type heat dissipation module according to claim 4, wherein the height of each of the second right top edges is equal to or less than a height of each of the first right top edges.

6. The airflow guiding type heat dissipation module according to claim 1, wherein an axial center line is defined as a line running across the first middle segments and the second middle segments, dividing the plurality of first fin members and the plurality of second fin members, and the first direction and the second direction are arranged in parallel with respect to the axial center line.

7. The airflow guiding type heat dissipation module according to claim 1, further comprising: a fan, disposed on a top end of the plurality of first fin members and a top end of the plurality of second fin members, a right half side of the fan arranged corresponding to the plurality of first inclined guiding sheets, and a left half side of the fan arranged corresponding to the plurality of second inclined guiding sheets.

8. The airflow guiding type heat dissipation module according to claim 1, further comprising: a plurality of heat pipes, a plurality of penetrated holes corresponding to a number of the plurality of heat pipes being disposed on the plurality of first middle segments and the plurality of second middle segments, each of the plurality of heat pipes passing through each of the corresponding plurality of penetrated holes.

9. The airflow guiding type heat dissipation module according to claim 1, wherein each of the first fin members and each of the second fin members respectively comprises a plurality of fixed convex sheets extended therefrom, and the fixed convex sheets located on each of the right segments of the first fin member and the second fin member are connected, and the fixed convex sheets located on each of the left segments of the first fin member and the second fin member are connected.

10. The airflow guiding type heat dissipation module according to claim 9, wherein each of the fixed convex sheets extends between each of the first fin members and each of the second fin members, an airflow channel is disposed between the adjacent first fin member and the second fin member.
